(19) United States
(12) Patent Application Publication
(10) Pub. No.: US 2013/0242683 A1
(43) Pub. Date: Sep. 19, 2013

(54) SEMICONDUCTOR DEVICE HAVING COMPENSATION CAPACITORS FOR STABILIZING OPERATION VOLTAGE

(71) Applicant: ELPIDA MEMORY, INC., Tokyo (JP)

(72) Inventors: Yasuhiko TANUMA, Tokyo (JP); Hisayuki NAGAMINE, Tokyo (JP)

(73) Assignee: ELPIDA MEMORY, INC., Tokyo (JP)

(21) Appl. No.: 13/784,268

(22) Filed: Mar. 4, 2013

(30) Foreign Application Priority Data
Mar. 15, 2012 (JP) 2012-058453

(51) Int. Cl. G11C 5/14

(52) U.S. Cl. CPC G11C 5/14
USPC 365/226

(57) ABSTRACT

Disclosed herein is a device that includes first and second memory cell arrays each including a plurality of memory cells, a first power supply line supplying a first voltage to the first memory cell array, a second power supply line supplying the first voltage to the second memory cell array, and a first capacitive element. The first capacitive element is electrically connected to the first power supply line and is electrically disconnected from the second power supply line when the first memory cell array is activated and the second memory cell array is deactivated. The first capacitive element is electrically connected to the second power supply line and is electrically disconnected from the first power supply line when the second memory cell array is activated and the first memory cell array is deactivated.

### BACKGROUND OF THE INVENTION

1. Field of the Invention

The present invention relates to a semiconductor device, and more particularly to a semiconductor device that includes a capacitive element for stabilizing a power supply voltage.

2. Description of Related Art

Semiconductor devices often include a capacitive element for stabilizing a power supply voltage. For example, Japanese Patent Application Laid-Open No. 2011-81855 discloses a Dynamic Random Access Memory (DRAM) that includes capacitive elements for stabilizing the operating voltage of sense amplifiers. Such capacitive elements are typically referred to as compensation capacitors.

A semiconductor memory device such as a DRAM typically includes a memory cell array that is divided into a plurality of areas. For example, a DRAM includes a memory cell array divided into a plurality of memory banks. The memory banks can be accessed in a nonexclusive manner. Since the operation of a memory bank is asynchronous with that of others, compensation capacitors are typically provided for each memory bank in order to prevent propagation of power supply noise between the memory banks.

The provision of compensation capacitors on each memory bank makes the needed compensation capacitors greater and increases the chip area. Such a problem is not limited to semiconductor memory devices such as a DRAM, but also occurs in other semiconductor devices that include a plurality of memory cell arrays. Under the circumstances, the inventors have made intensive studies to reduce the chip area of a semiconductor device that includes compensation capacitors.

### SUMMARY

In one embodiment, there is provided a device that includes: first and second memory cell arrays each including a plurality of memory cells; a first power supply line supplying a first voltage to the first memory cell array; a second power supply line supplying the first voltage to the second memory cell array; and a first capacitive element. The first capacitive element is electrically connected to the first power supply line and is electrically disconnected from the second power supply line when the first memory cell array is activated and the second memory cell array is deactivated. The first capacitive element is electrically connected to the second power supply line and is electrically disconnected from the first power supply line when the second memory cell array is activated and the first memory cell array is deactivated.

In another embodiment, there is provided a device that includes: first and second memory cell arrays each including a plurality of memory cells and a plurality of sense amplifier circuits that amplifies data read from the memory cells, the first and second memory cell arrays being nonexclusively activated; a first power supply generation circuit arranged in a first circuit area arranged between the first and second memory cell arrays and supplying a first voltage to the sense amplifier circuits of the first memory cell array via a first power supply line; a second power supply generation circuit arranged in the first circuit area and supplying the first voltage to the sense amplifier circuits of the second memory cell array via a second power supply line; a first capacitive element arranged in the first circuit area; a first switch element connected between the first capacitive element and the first power supply line; a second switch element connected between the first capacitive element and the second power supply line; and a capacitance control circuit controlling at least the first and second switch elements, the capacitance control circuit bringing the first switch element into an ON state and the second switch element into an OFF state when the first memory cell array is activated and the second memory cell array is deactivated, and bringing the second switch element into an ON state and the first switch element into an OFF state when the second memory cell array is activated and the first memory cell array is deactivated.

In still another embodiment, such a device is provided that comprises: a first sense amplifier array for a first memory cell array; a second sense amplifier array for a second memory cell array; a first power line conveying a first power voltage to the first sense amplifier array; a second power line conveying a second power voltage to the second sense amplifier array, the second power voltage being substantially equal to the first power voltage; a common capacitor; a first switch connected between the first power line and the common capacitor, the first switch being configured to be one of conductive and non-conductive states in response to a first control signal; and a second switch connected between the second power line and the common capacitor, the second switch being configured to be one of conductive and non-conductive states in response to a second control signal.

### BRIEF DESCRIPTION OF THE DRAWINGS

FIG. 1 is a block diagram showing the configuration of a semiconductor device according to an embodiment of the present invention;

FIG. 2 is a plan view for explaining the chip layout of the semiconductor device shown in FIG. 1;

FIG. 3 is a plan view showing the layout of the area AB shown in FIG. 2 in more details;

FIG. 4 is a circuit diagram of sense blocks SB and sense amplifier control circuits CNT shown in FIG. 3;

FIG. 5 is a block diagram showing the configuration of the capacitance circuit shown in FIG. 1;

FIG. 6 is a plan view showing the layout of the capacitance circuit in the area AB shown in FIG. 2 according to a first embodiment of the present invention;

FIG. 7 is a simplified circuit diagram showing essential parts of the circuit shown in FIG. 6;

FIG. 8 is a plan view showing the layout of the capacitance circuit in the area AB shown in FIG. 2 according to a modified embodiment of the present invention;

FIG. 9 is a circuit diagram of the capacitance control circuits used in the first embodiment of the present invention;

FIG. 10A is a timing chart for explaining the operation of the semiconductor device according to the first embodiment of the present invention in a case where the memory bank A is selected;

FIG. 10B is a timing chart for explaining the operation of the semiconductor device according to the first embodiment of the present invention in a case where the memory bank B is selected;

FIG. 10C is a timing chart for explaining the operation of the semiconductor device according to the first embodiment of the present invention in a case where the memory banks A and B are both selected;

FIG. 11A is a schematic diagram for explaining the relationship between the power supply generation circuits 41A to 41D and the switch elements 130A to 130D in a case where the power supply generation circuit 41A is activated;

FIG. 11B is a schematic diagram for explaining the relationship between the power supply generation circuits 41A to 41D and the switch elements 130A to 130D in a case where the power supply generation circuit 41B is activated;

FIG. 11C is a schematic diagram for explaining the relationship between the power supply generation circuits 41A to 41D and the switch elements 130A to 130D in a case where the power supply generation circuit 41C is activated;

FIG. 11D is a schematic diagram for explaining the relationship between the power supply generation circuits 41A to 41D and the switch elements 130A to 130D in a case where the power supply generation circuit 41D is activated;

FIG. 12 is a schematic plan view showing a specific configuration of the capacitive element according to a first example;

FIG. 13 is a schematic plan view showing a specific configuration of the capacitive element according to a second example;

FIG. 14 is a schematic plan view showing a first connection example of the capacitive element 110AB having the structure shown in FIG. 12 and the switch elements 130A and 130B;

FIG. 15 is a schematic plan view showing a second connection example of the capacitive element 110AB having the structure shown in FIG. 12 and the switch elements 130A and 130B;

FIG. 16 is a plan view showing the layout of the capacitance circuit in the area BC shown in FIG. 2 according to a second embodiment of the present invention;

FIG. 17 is a simplified circuit diagram showing essential parts of the circuit according to the second embodiment of the present invention;

FIG. 18 is a plan view showing the layout of the capacitance circuit in the area BC shown in FIG. 2 according to a third embodiment of the present invention;

FIG. 19 is a simplified circuit diagram showing essential parts of the circuit according to the third embodiment of the present invention;

FIG. 20 is a plan view showing the layout of the capacitance circuit in the area AB shown in FIG. 2 according to a fourth embodiment of the present invention;

FIG. 21 is a simplified circuit diagram showing essential parts of the circuit shown in FIG. 20;

FIG. 22 is a circuit diagram of the capacitance control circuits 120A and 120B used in the fourth embodiment of the present invention;

FIG. 23A is a timing chart for explaining the operation of the semiconductor device according to the fourth embodiment of the present invention in a case where the memory bank A is selected;

FIG. 23B is a timing chart for explaining the operation of the semiconductor device according to the fourth embodiment of the present invention in a case where the memory bank B is selected; and

FIG. 23C is a timing chart for explaining the operation of the semiconductor device according to the fourth embodiment of the present invention in a case where the memory banks A and B are both selected.

### DETAILED DESCRIPTION OF THE EMBODIMENTS

The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

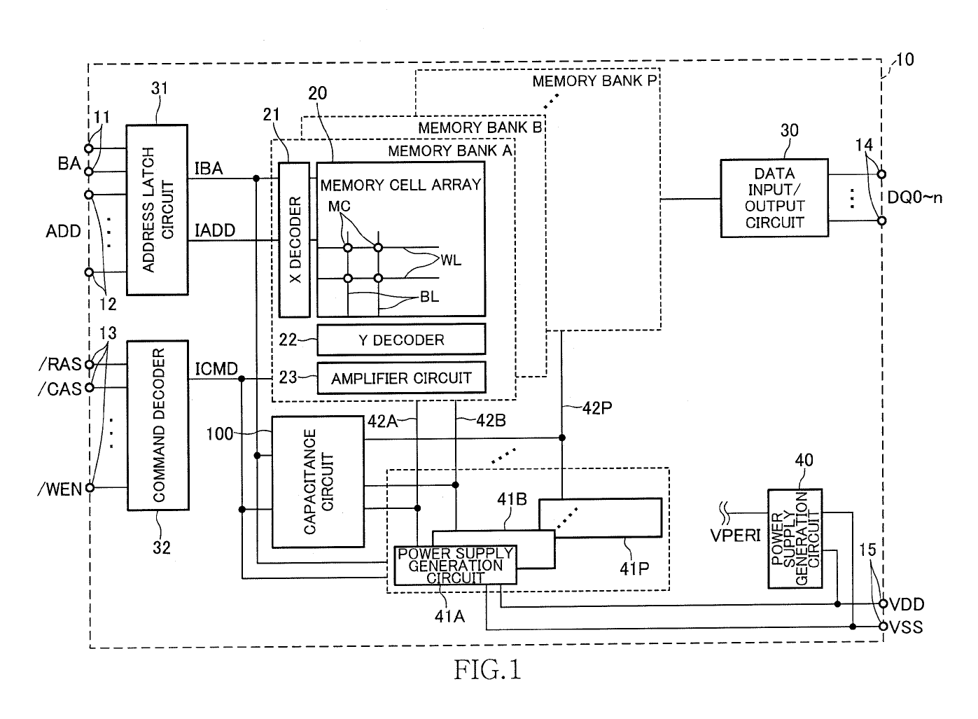

Referring now to FIG. 1, the semiconductor device 10 according to the embodiment of the present invention is a DRAM and is integrated on a single semiconductor chip. It should be noted that the semiconductor device according to the present invention is not limited to a DRAM, and may be other types of semiconductor memory devices such as a static random access memory (SRAM), a phase change random access memory (PRAM), a resistance random access memory (ReRAM), and a flash memory. Semiconductor logic devices having built-in memory cell arrays are also applicable.

As shown in FIG. 1, the semiconductor device 10 according to this embodiment includes 16 memory banks A to P. The memory banks A to P are units capable of individual command execution. The memory banks can thus be accessed in a nonexclusive manner. In the present invention, the number of memory banks is not limited in particular. For example, the semiconductor device may include eight memory banks or 32 memory banks. The memory banks A to P are selected based on an internal bank address signal IBA.

Each of the memory banks A to P includes a memory cell array 20, an X decoder 21, a Y decoder 22, and an amplifier circuit 23. The memory cell array 20, as will be described in detail later, includes a plurality of word lines WL and a plurality of bit lines BL, at intersections of which are arranged memory cells MC. The word lines WL and bit lines BL are selected based on an internal address signal IADD.

Specifically, when an internal command signal ICMD indicates a row access, the internal address signal IADD is supplied to the X decoder 21 in the memory bank selected by the internal bank address signal IBA. This selects any one of the word lines WL in the selected memory bank. When the internal command signal ICMD indicates a column access, the internal address signal IADD is supplied to the Y decoder 22 in the memory bank selected by the internal bank address signal IBA. This selects some of the bit lines BL in the selected memory bank. The selected bit lines BL are connected to a data input/output circuit 30. In a read operation, read data DQ0 to DQn read from the memory cells MC is thus output from data terminals 14. In a write operation, write data DQ0 to DQn input to the data terminals 14 is written into the memory cells MC through the data input/output circuit 30.

The internal bank address signal IBA and the internal address signal IADD are supplied from an address latch circuit 31. The address latch circuit 31 latches a bank address signal BA supplied from bank address terminals 11 and an address signal ADD supplied from address terminals 12. The internal command signal ICMD is supplied from a command decoder 32. The command decoder 32 decodes command signals CMD supplied from command terminals 13 and activates a predetermined internal command signal ICMD based on the decoding result. As shown in FIG. 1, the command signals CMD include a combination of a plurality of signals such as a row address strobe signal /RAS, a column address strobe signal/CAS, and a write enable signal /WEN.

The semiconductor device 10 according to the present embodiment further includes a power supply generation circuit 40 which is in common use, and power supply generation circuits 41A to 41P which are allocated for the memory banks A to P, respectively. The power supply generation circuits 40 and 41A to 41P generate a predetermined internal voltage based on external voltages VDD and VSS which are supplied from outside through power supply terminals 15. The power supply generation circuit 40 generates an internal voltage VPERI. The internal voltage VPERI is mainly supplied to peripheral circuits. The peripheral circuits refer to circuits that are allocated for the memory banks A to P in common. The peripheral circuits include the data input/output circuit 30, the address latch circuit 31, and the command decoder 32 shown in FIG. 1. The power supply generation circuits 41A to 41P generate internal voltages for driving sense amplifier circuits to be described later. The internal voltages are supplied to the corresponding memory banks A to P through power supply lines 42A to 42P, respectively. The power supply generation circuits 41A to 41P are activated based on respective corresponding internal bank address signals IBA. As will be described later, the activated power supply generation circuits 41A to 41P enhance their ability to drive the internal voltage as compared to when not activated. In other words, the power supply generation circuits 41A to 41P continue supplying a predetermined internal voltage to the corresponding power supply lines 42A to 42P even in a deactivated state. The driving ability here is significantly lower than when activated. FIG. 1 shows the power supply lines 42A to 42P by a single line each. In fact, the power supply lines 42A to 42P are each composed of a plurality of power supply lines for supplying a plurality of types of voltages. In the present Specification, the power supply lines 42A to 42P may be referred to as “array power supply lines.”

As shown in FIG. 1, the power supply lines 42A to 42P are connected to a capacitance circuit 100. As will be described in detail later, the capacitance circuit 100 controls compensation capacitance values to be given to the power supply lines 42A to 42P based on the internal bank address signal IBA and the internal command signal ICMD.

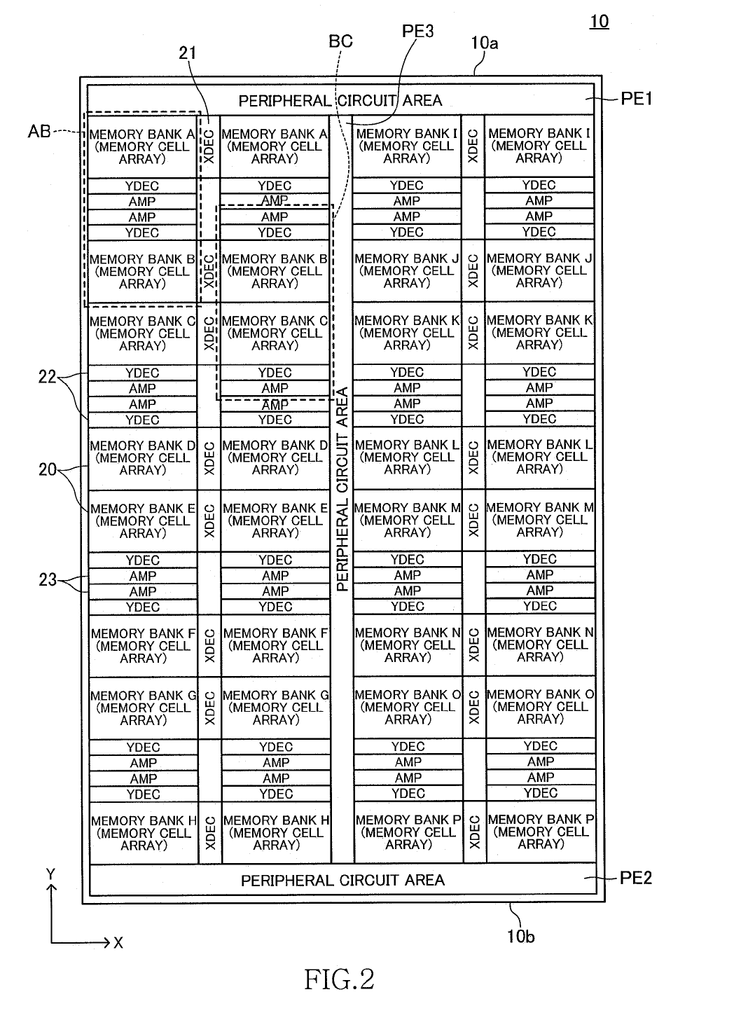

Turning to FIG. 2, the semiconductor device 10 according to the present embodiment includes a first peripheral circuit area PE1 which is arranged along one end 10a in a Y direction, a second peripheral circuit area PE2 which is arranged along the other end 10b in the Y direction, and a third peripheral circuit area PE3 which is arranged to extend in the Y direction in the center of an X direction. The first peripheral circuit area PE1 is an area where external terminals such as the bank address terminals 11, the address terminals 12, and the command terminals 13, and command/address system peripheral circuits such as the address latch circuit 31 and the command decoder 32 are laid out. The second peripheral circuit area PE2 is an area where external terminals such as the data terminals 14 and data system peripheral circuits such as the data input/output circuit 30 are laid out. Various types of other peripheral circuits are laid out in the third peripheral circuit area PE3. The semiconductor device 10 according to the present embodiment thus has an edge pad structure that the external terminals are arranged on chip edges. However, the present invention is not limited thereto. For example, a center pad structure where external terminals are arranged in the chip center may be employed.

The memory banks A to P are laid out in the area sandwiched between the peripheral circuit areas PE1 and PE2. As shown in FIG. 2, the memory cell arrays 20 included in the memory banks A to P are each divided into two in the X direction. The X decoders 21 are arranged in the areas sandwiched between such memory cell arrays 20. The Y decoders 22 and the amplifier circuits 23 are arranged between memory cell arrays 20 adjoining in the Y direction.

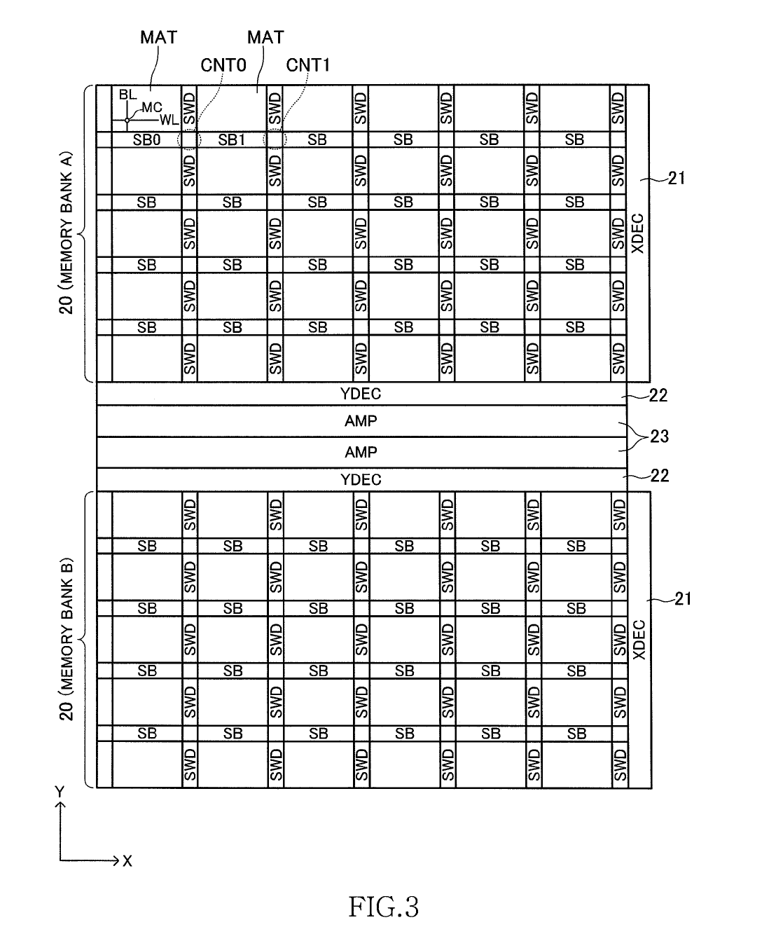

Turning to FIG. 3, each memory cell array 20 includes a plurality of memory mats MAT which are laid out in a matrix. Sub word driver circuits SWD are arranged between memory mats MAT adjoining in the X direction. Sense blocks SB are arranged between memory mats MAT adjoining in the Y direction. The sub word driver circuits SWD drive the word lines WL. The sense blocks SB amplify data appearing on the bit lines BL. As will be described later, each sense block SB includes a plurality of sense amplifier circuits SA. Sense amplifier control circuits CNT for controlling the sense blocks SB are arranged in cross areas where a plurality of sense blocks SB extending in the X direction and a plurality of sub word driver circuits SWD cross each other.

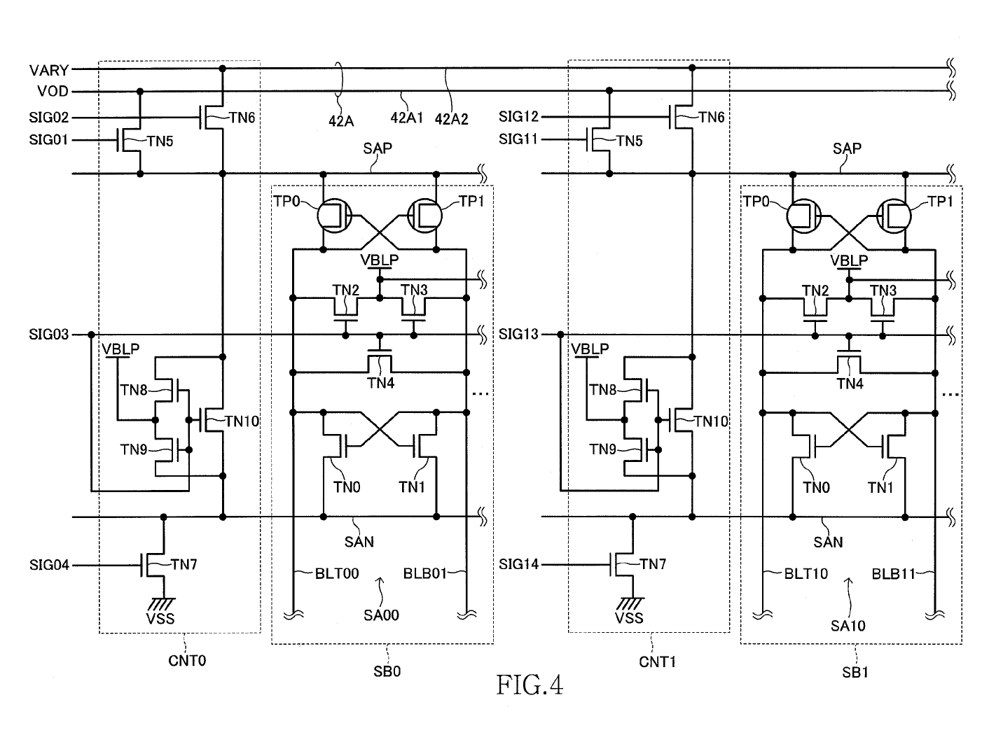

The circuit diagram shown in FIG. 4 corresponds to the sense blocks SB0 and SB1 and the sense amplifier control circuits CNT0 and CNT1 shown in FIG. 3.

As shown in FIG. 4, the sense block SB0 includes a sense amplifier circuit SA00 which is provided for a pair of bit lines BLT00 and BLB01. The sense amplifier circuit SA00 includes cross-coupled P-channel MOS transistors TP0 and TP1 and cross-coupled N-channel MOS transistors TN0 and TN1. The sources of the transistors TP0 and TP1 are connected to sense amplifier driving wiring SAP. The sources of the transistors TN0 and TN1 are connected to sense amplifier driving wiring SAN. The drains of the transistors TP0 and TN0 (the gate electrodes of the transistors TP1 and TN1) are connected to the bit line BLT00. The drains of the transistors TP1 and TN1 (the gate electrodes of the transistors TP0 and TN0) are connected to the bit line BLB01. The bit lines BLT00 and BLB01 are paired up. With such a configuration, when the sense amplifier driving wiring SAP is driven to a high level and the sense amplifier driving wiring SAN is driven to a low level, a potential difference appearing between the pair of bit lines BLT00 and BLB01 is amplified by the sense amplifier circuit SA00.

The sense amplifier circuit SA00 includes precharging transistors TN2 to TN4. When the transistors TN2 to TN4 are turned on, the pair of bit lines BLT00 and BLB01 are precharged to a precharge potential VBLP. The transistors TN2 to TN4 are controlled by a control signal SIG03.

Although not shown in the diagram, the sense block SB0 includes such sense amplifier circuits SA00, SA01, SA02, . . . for respective bit line pairs. The other sense amplifier circuits SA01, SA02, . . . have the same circuit configuration. The sense amplifier driving wiring SAP and SAN is connected to all the sense amplifier circuits SA00, SA01, SA02, . . . in the sense block SB0 in common.

The sense amplifier control circuit CNT0 is a circuit for controlling the sense amplifier circuits SA00, SA01, SA02, . . . in the sense bock SB0. The sense amplifier control circuit CNT0 includes an N-channel MOS transistor TN5 which is connected between a power supply line 42A1 and the sense amplifier driving wiring SAP, and an N-channel MOS transistor TN6 which is connected between a power supply line 42A2 and the sense amplifier driving wiring SAP. The power supply lines 42A1 and 42A2 are wiring that constitutes the power supply line 42A shown in FIG. 1. The power supply generation circuit 41A supplies internal voltages VOD and VARY to the power supply lines 42A1 and 42A2, respectively. The internal voltage VOD is an overdriving voltage and is higher than the internal voltage VARY. The internal voltage VARY is a high-level voltage to be supplied to either one of a pair of bit lines. Control signals SIG01 and SIG02 are supplied to the gate electrodes of the transistors TN5 and TN6, respectively.

The sense amplifier control circuit CNT0 further includes an N-channel MOS transistor TN7 which is connected between the sense amplifier driving wiring SAN and a ground level VSS. The ground level VSS is a low-level voltage to be supplied to the other of the pair of bit lines. A control signal SIG04 is supplied to the gate electrode of the transistor TN7.

With such a configuration, when the control signals SIG02 and SIG04 are activated, the sense amplifier driving wiring SAP and the sense amplifier driving wiring SAN are driven to the VARY level and the VSS level, respectively. As a result, a potential difference occurring between the pair of bit lines BLT00 and BLB01 is amplified by the sense amplifier SA00. Immediately before the activation of the control signal SIG02, the control signal SIG01 is temporarily activated to overdrive the sense amplifier driving wiring SAP. The control signals SIG01, SIG02, and SIG04 are activated at predetermined timing if the internal command signal ICMD indicates a row access, i.e., if an active command is issued.

The sense amplifier control circuit CNT0 also includes precharging transistors TN8 to TN10. When the transistors TN8 to TN10 are turned on, the sense amplifier driving wiring SAP and SAN is precharged to the precharge potential VBLP. The transistors TN8 to TN10 are controlled by the control signal SIG03. The control signal SIG03 is activated at predetermined timing if the internal command signal ICMD indicates the end of an access, i.e., when a precharge command is issued.

The sense block SB1 has the same circuit configuration as that of the foregoing sense block SB0. A plurality of sense amplifier circuits SA10, SA11, SA12, . . . included in the sense block SB1 are controlled by the sense amplifier control circuit CNT1. As shown in FIG. 4, the power supply lines 42A1 and 42A2 are allocated for the plurality of sense amplifier control circuits CNT including the sense amplifier control circuits CNT0 and CNT1 in common.

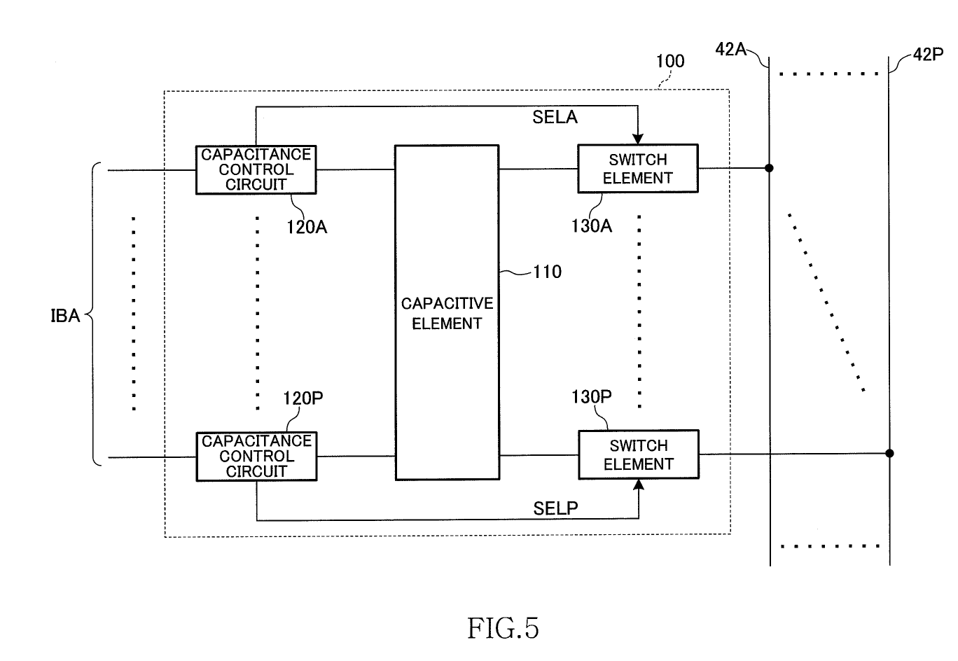

Turning to FIG. 5, the capacitance circuit 100 includes a capacitive element 110, capacitance control circuits 120A to 120P, and switch elements 130A to 130P. The capacitive element 110 is a compensation capacitor for the power supply lines 42A to 42P. Which of the power supply lines 42A to 42P to connect the capacitive element 110 to through the switch elements 130A to 130P is controlled by select signals SELA to SELP. The select signals SELA to SELP are generated by the respective corresponding capacitance control circuits 120A to 120P. The capacitance control circuits 120A to 120P are allocated for the respective memory banks A to P, and control the corresponding select signals SELA to SELP based on whether the memory banks are selected.

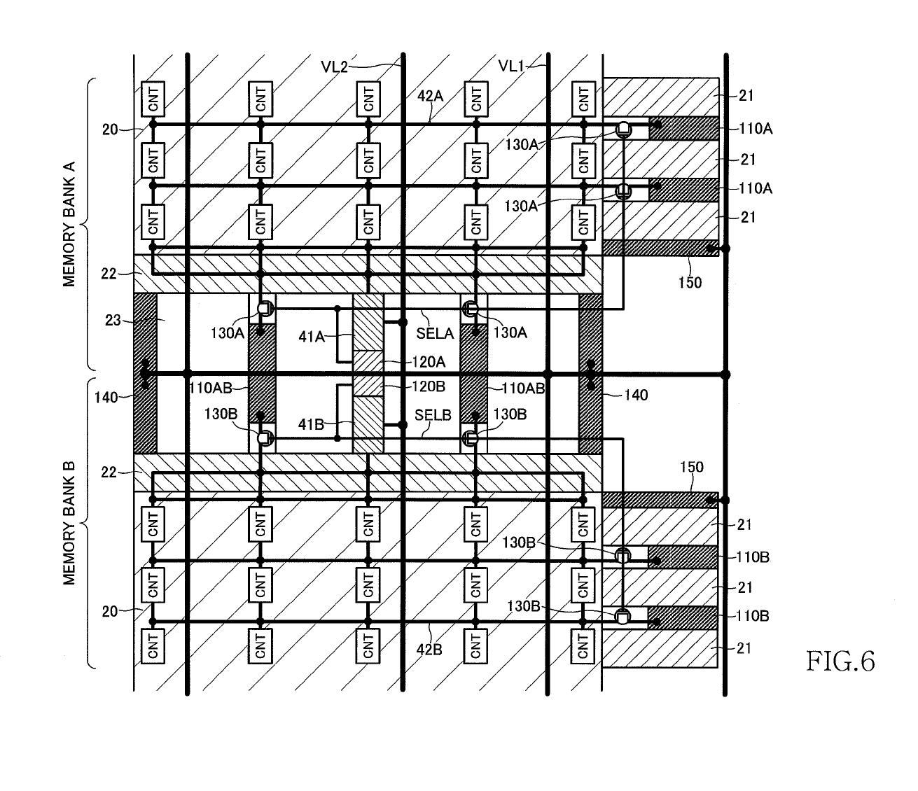

Turning to FIG. 6, the capacitance circuit 100 according to the first embodiment includes capacitive elements 110AB, the capacitance control circuits 120A and 120B, and the switch elements 130A and 130B, which are arranged in the area where amplifier circuits 23 are arranged in the memory banks A and B. The capacitive elements 110AB are apart of the capacitive element 110 shown in FIG. 5. The power supply generation circuits 41A and 41B, which supply the internal voltages VOD and VARY to the power supply lines 42A and 42B, are also arranged in that area. A power supply line VL1 shown in FIG. 6 is wiring to which the internal voltage VPERI is supplied. The power supply line VL1 is a power supply line common to the memory bank A to P and the peripheral circuits. In the present Specification, the power supply line VL1 may be referred to as a “peripheral circuit power supply line.” There are capacitive elements for stabilizing the internal voltage VPERI. Of these, some capacitive elements 140 are formed in the area where the amplifier circuits 23 are arranged. Some other capacitive elements 150 are formed in the areas where X decoders 21 are arranged. A power supply line VL2 shown in FIG. 6 is wiring for supplying an operating voltage to the power supply generation circuits 41A and 41B.

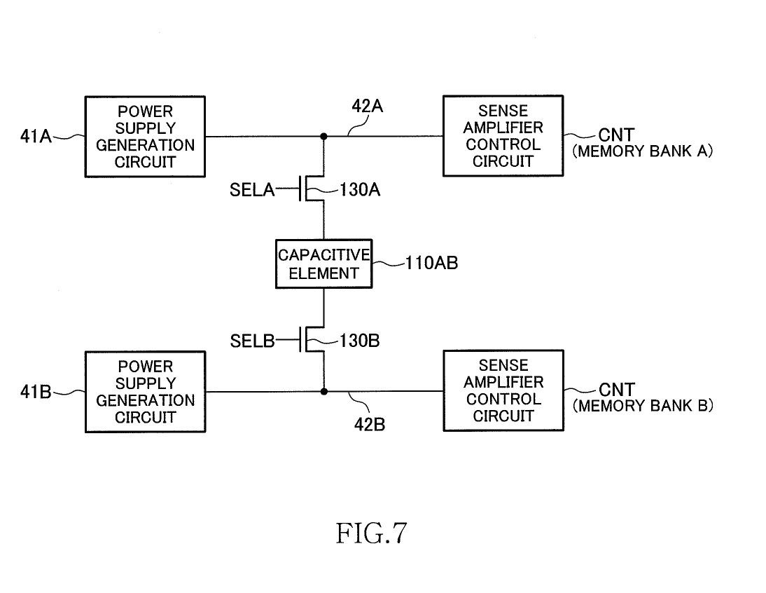

In the present embodiment, the capacitive elements 110AB are allocated for the power supply lines 42A and 42B in common. In other words, the capacitive elements 110AB are compensation capacitors common to the memory banks A and B. The connections between the capacitive elements 110AB and the power supply lines 42A and 42B are controlled by the switch elements 130A and 130B based on the select signals SELA and SELB supplied from the capacitance control circuits 120A and 120B. FIG. 7 is a simplified circuit diagram showing essential parts of the circuit shown in FIG. 6. In the present Specification, the switch element 130A shown in FIGS. 6 and 7 may be referred to as a “first switch element.” The switch element 130B may be referred to as a “second switch element.” The capacitive element 110AB may be referred to as a “first capacitive element.” The power supply generation circuit 41A may be referred to as a “first power supply generation circuit.” The power supply generation circuit 41B may be referred to as a “second power supply generation circuit.”

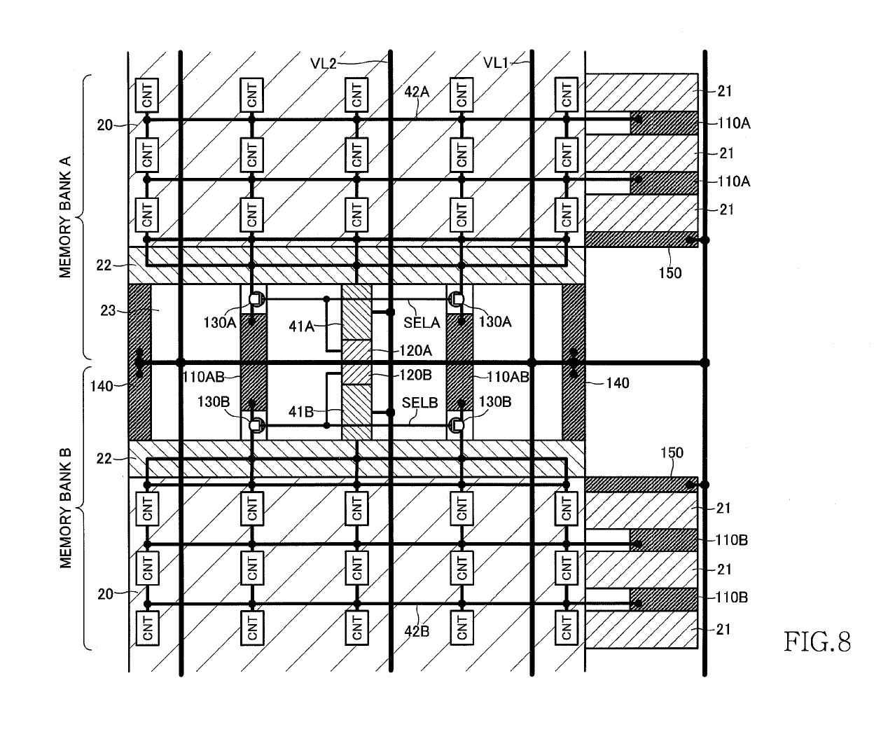

Capacitive elements 110A and 110B, which are another part of the capacitive element 110 shown in FIG. 5, are arranged in the areas where the X decoders 21 are arranged in the respective memory banks A and B. The capacitive elements 110A and 110B are compensation capacitors individually allocated for the memory banks A and B. In the example shown in FIG. 6, switch elements 130A and 130B are also interposed between the capacitive elements 110A and 110B and the power supply lines 42A and 4213. As shown in FIG. 8, such switch elements 130A and 130B may be deleted.

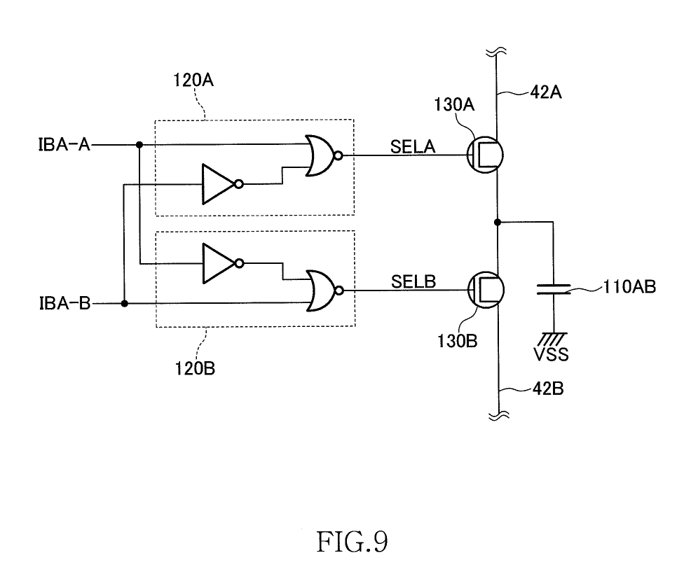

Turning to FIG. 9, the capacitance control circuit 120A includes a NOR gate circuit that receives a bank select signal IBA-A and the inverted signal of a bank select signal IBA-B. The bank select signal IBA-A is activated to a high level when the memory bank A is selected. The situation when the memory bank A is selected corresponds to that the bank address signal BA input in synchronization with an active command designates the memory bank A. Similarly, the bank select signal IBA-B is activated when the memory bank B is selected.

With such a configuration, the capacitance control circuit 120A deactivates the select signal SELA to a high level only when the memory bank A is not selected and the memory bank B is selected. In the other cases, the capacitance control circuit 120A activates the select signal SELA to a low level. As shown in FIG. 9, in the present embodiment, the switch elements 130A and 130B are both composed of a P-channel MOS transistor. The activation of the select signal SELA to a low level therefore connects the power supply line 42A to one end of the capacitive element 110AB. The other end of the capacitive element 110AB is fixed to the ground level VSS.

Similarly, the capacitance control circuit 120B includes a NOR gate circuit that receives the bank select signal IBA-B and the inverted signal of the bank select signal IBA-A. The capacitance control circuit 120B deactivates the select signal SELB to a high level only when the memory bank B is not selected and the memory bank A is selected. In the other cases, the capacitance control circuit 120B activates the select signal SELB to a low level.

An operation of the capacitance circuit 100 according to the first embodiment will be explained next.

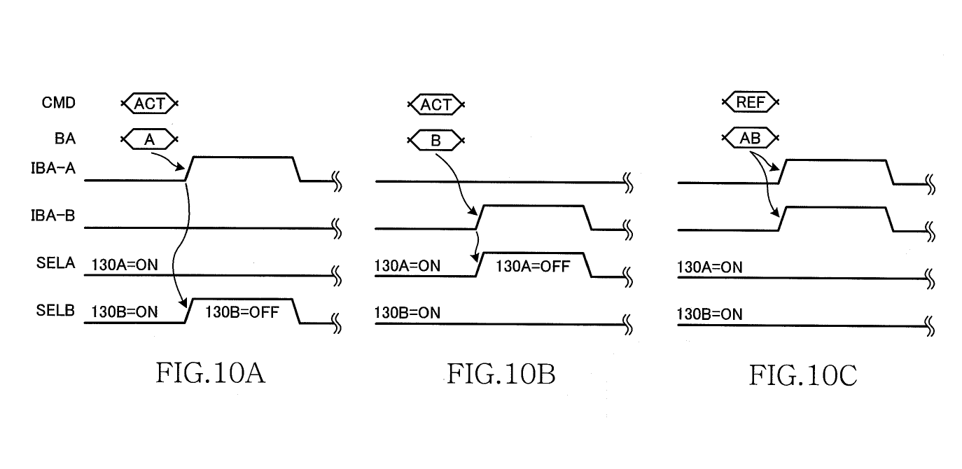

As shown in FIG. 10A, before the issuance of an active command ACT, i.e., when neither of the memory banks A and B is selected, the select signals SELA and SELB are both at a low level and the switch elements 130A and 130B are both on. In such a state, both the power supply generation circuits 41A and 41B are in an inactive state, and are supplying currents to the inactive memory banks A and B with such ability as maintains the levels of the internal voltages VOD and VARY. Since the inactive memory banks A and B hardly consume the internal voltages VOD and VARY, the power supply generation circuits 41A and 41B may have only slight current-supplying ability.

When an active command ACT designated for the memory bank A is issued, the bank select signal IBA-A changes to a high level. In response, the power supply generation circuit 41A is activated to enhance the ability to drive the internal voltages VOD and VARY. Here, the bank select signal IBA-B remains at the low level. Consequently, the select signal SELB changes to a high level to turn the switch element 130B off, and the power supply line 42B is disconnected from the capacitive element 110AB. Subsequently, the control signals SIG01 and SIG02 shown in FIG. 4 are activated, and the sense block SB operates with a current consumption through the power supply line 42A. The connection of the power supply line 42A with the capacitive element 110AB stabilizes the voltages VOD and VARY on the power supply line 42A. Since the switch element 130B is off, noise on the power supply line 42A will not propagate to the inactive memory bank B.

The operation when the memory bank B is selected is similar to the foregoing. As shown in FIG. 10B, the switch element 130A turns off to disconnect the power supply line 42A from the capacitive element 110AB. As a result, the internal voltages VOD and VARY on the power supply line 42B are stabilized by the capacitive element 110AB. Since the switch element 130A is off, noise on the power supply line 42B will not propagate to the inactive memory bank A.

As shown in FIG. 100, when a refresh command REF designated for the memory banks A and B is issued, the bank select signals IBA-A and IBA-B both change to a high level. The select signals SELA and SELB both remain at the low level. Both the switch elements 130A and 130B are thereby maintained on. When the bank select signals IBA-A and IBA-B change to the high level, the power supply generation circuits 41A and 41B are activated to enhance the current-supplying ability. This maintains the levels of the internal voltages VOD and VARY on the power supply lines 42A and 42B even if the sense block SB makes an operation. Note that a refresh command REF need not necessarily be issued with the designation of memory banks. When a refresh command REF is issued, a refresh operation may be automatically performed on all the memory banks A to P. A refresh command REF is not the only command to be designated for a plurality of memory banks. Other commands may include such designation.

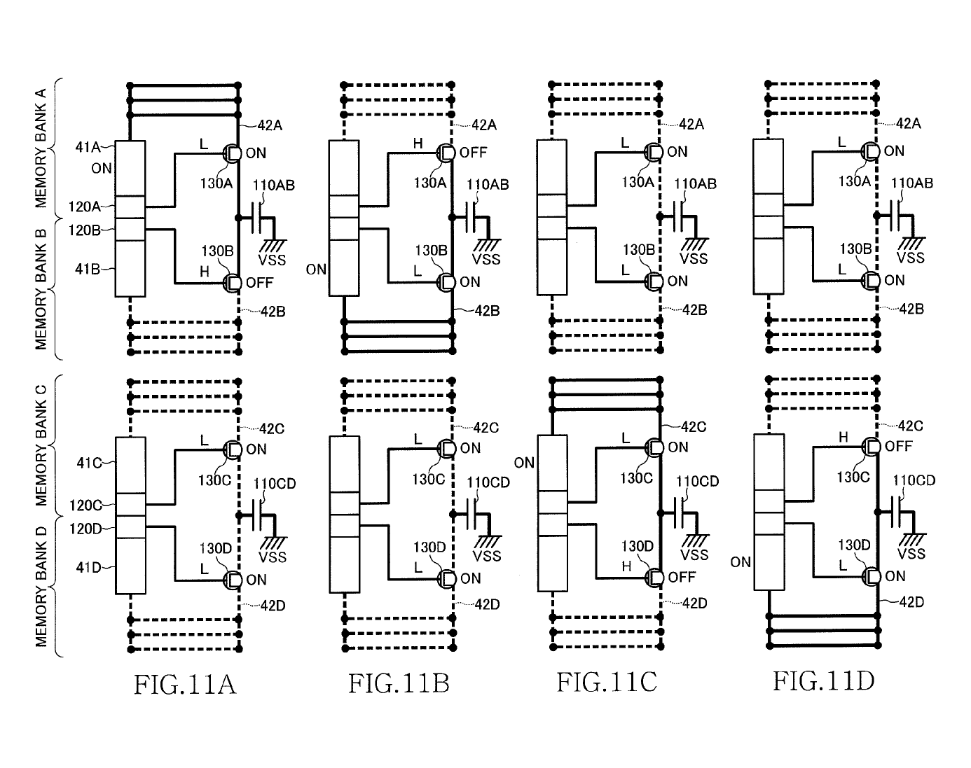

Turning to FIGS. 11A to 11D, the power supply lines 42 shown in solid lines are ones driven by the activated power supply generation circuits. The power supply lines 42 shown in broken lines are ones driven by the inactive power supply generation circuits.

As shown in FIG. 11A, when the power supply generation circuit 41A is activated, the switch elements 130A, 130C, and 130D turn on and the switch element 130B turns off. In the memory banks A and B, the power supply line 42A is connected to the capacitive element 110AB and the power supply line 42B is disconnected from the capacitive element 110AB. The power supply line 42B is supplied with the internal voltages VOD and VARY from the inactive power supply generation circuit 41B. For the memory banks C and D, the power supply lines 42C and 42D are connected to a capacitive element 110CD. The power supply lines 42C and 42D are supplied with the internal voltages VOD and VARY from the inactive power supply generation circuits 41C and 41D. The capacitive element 110CD is a part of the capacitive element 110 shown in FIG. 5.

As shown in FIG. 11B, when the power supply generation circuit 41B is activated, the switch elements 130B, 130C, and 130D turn on and the switch element 130A turns off. For the memory banks A and B, the power supply line 42B is connected to the capacitive element 110AB and the power supply line 42A is disconnected from the capacitive element 110AB. The power supply line 42A is supplied with the internal voltages VOD and VARY from the inactive power supply generation circuit 41A. For the memory banks C and D, the power supply lines 42C and 42D are connected to the power supply lines 110CD. The power supply lines 42C and 42D are supplied with the internal voltages VOD and VARY from the inactive power supply generation circuits 41C and 41D.

As shown in FIG. 11C, when the power supply generation circuit 41C is activated, the switch elements 130A, 130B, and 130C turn on and the switch element 130D turns off. For the memory banks C and D, the power supply line 42C is connected to the capacitive element 110CD and the power supply line 42D is disconnected from the capacitive element 110CD. The power supply line 42D is supplied with the internal voltages VOD and VARY from the inactive power supply generation circuit 41D. For the memory banks A and B, the power supply lines 42A and 42B are connected to the capacitive element 110AB. The power supply lines 42A and 42B are supplied with the internal voltages VOD and VARY from the inactive power supply generation circuits 41A and 41B.

As shown in FIG. 11D, when the power supply generation circuit 41D is activated, the switch elements 130A, 130B, and 130D turn on and the switch element 130C turns off. For the memory banks C and D, the power supply line 42D is connected to the capacitance element 110CD and the power supply line 42C is disconnected from the capacitance element 110CD. The power supply line 42C is supplied with the internal voltages VOD and VARY from the inactive power supply generation circuit 41C. For the memory bank A and B, the power supply lines 42A and 42B are connected to the capacitive element 110AB. The power supply lines 42A and 42B are supplied with the internal voltages VOD and VARY from the inactive power supply generation circuits 41A and 41B.

While the foregoing description has concentrated on the memory banks A to D (memory banks A and B in particular), the other memory banks also share capacitive elements in a similar manner. For example, the memory banks E and F share a not-shown capacitive element 110EF. The memory banks G and H share a not-shown capacitive element 110 GH.

As described above, in the semiconductor device 10 according to the present embodiment, two memory banks share a capacitive element. This can reduce the area occupied by the capacitive elements on the chip while stabilizing the internal voltages VOD and VARY. If either one of the two memory banks sharing a capacitive element is activated and the other is deactivated, the power supply line of the deactivated memory bank is disconnected from the capacitive element. Power supply noise caused by the operation of the activated memory bank is thus prevented from propagating to the deactivated memory bank. If the two memory banks sharing a capacitive element are both deactivated, the power supply lines corresponding to the two memory banks are both connected to the capacitive element, whereby the voltages of the power supply lines can be stabilized.

Next, specific configurations of the capacitive element 110AB and other elements will be described.

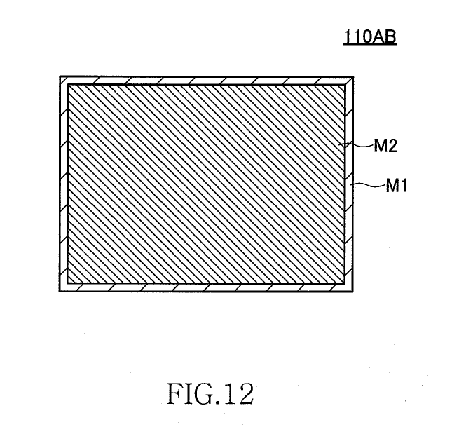

Turning to FIG. 12, the capacitive element 110AB according to the first example has a structure that a lower layer of conductive film M1 and an upper layer of conductive film M2 overlap when seen in a plan view. In such a case, an interlayer insulation film interposed between the conductive films M1 and M2 functions as a capacitor insulating film. According to the present example, the capacitive element 110AB can be formed in an unused space of a wiring layer.

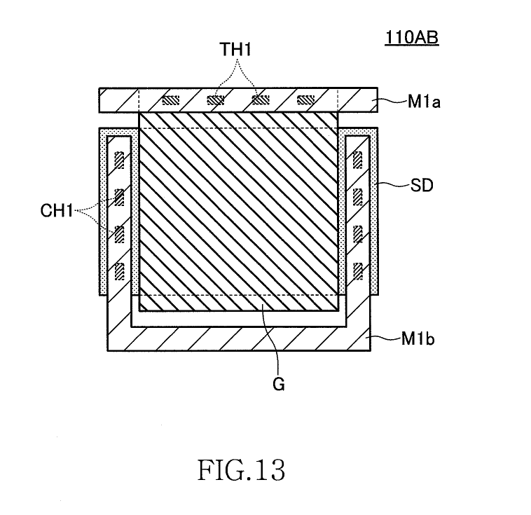

Turning to FIG. 13, the capacitive element 110AB according to the second example has a structure that a gate electrode G and a diffusion layer SD overlap when seen in a plan view. The gate electrode G is connected to a conductive film M1a via through hole conductors TH1. The diffusion layer SD is connected to a conductive film M1b via contact hole conductors CH1. In such a case, a gate insulation film interposed between the gate electrode G and the diffusion layer SD functions as a capacitor insulating film. According to the present example, the capacitive element 110AB can be formed in an unused space of the semiconductor substrate.

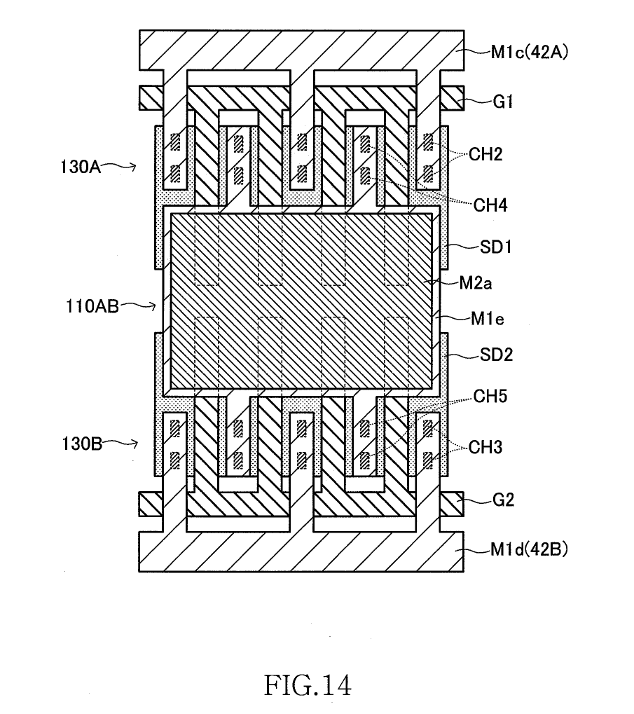

Turning to FIG. 14, the switch elements 130A and 130B each include a plurality of transistors connected in parallel.

Specifically, the switch element 130A includes a plurality of source/drain diffusion layers SD1 which are alternately arranged, and a plurality of gate electrodes G1 which are arranged on the semiconductor substrate between the source/drain diffusion layers SD1, respectively. Of the source/drain diffusion layers SD1, ones functioning as a source are connected to a conductive film M1c via contact holes CH2. The conductive film M1c functions as the power supply line 42A. Of the source/drain function layers SD1, ones functioning as a drain are connected to a conductive film M1e via contact holes CH4.

Similarly, the switch element 130B includes a plurality of source/drain diffusion layers SD2 which are alternately arranged, and a plurality of gate electrodes G2 which are arranged on the semiconductor substrate between the source/drain diffusion layers SD2, respectively. Of the source/drain diffusion layers SD2, ones functioning as a source are connected to a conductive film M1d via contact holes CH3. The conductive film M1d functions as the power supply line 42B. Of the source/drain diffusion layers SD2, ones functioning as a drain are connected to the conductive film M1e via contact holes CH5.

A conductive film M2a is arranged above the conductive film M1e in an overlapping position when seen in a plan view, whereby the capacitive element 110AB is formed.

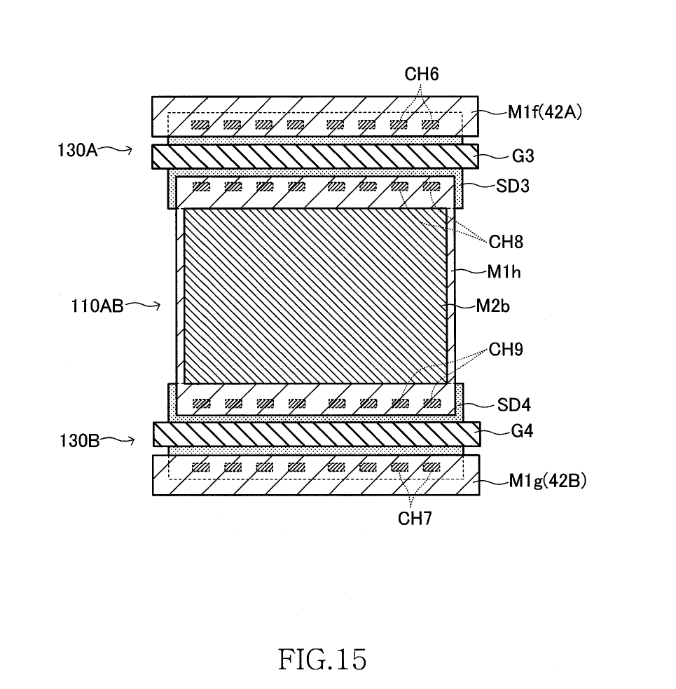

Turning to FIG. 15, the switch elements 130A and 130B each include a transistor having a large channel width.

Specifically, the switch element 130A includes source/drain diffusion layers SD3 and a gate electrode G3 which is arranged on the semiconductor substrate between the source/drain diffusion layers SD3. Of the source/drain diffusion layers SD3, the one functioning as a source is connected to a conductive film M1f via contact holes CH6. The conductive film M1f functions as the power supply line 42A. Of the source/drain diffusion layers SD3, the one functioning as a drain is connected to a conductive film M1h via contact holes CH8.

Similarly, the switch element 130B includes source/drain diffusion layers SD4 and a gate electrode G4 which is arranged on the semiconductor substrate between the source/drain diffusion layers SD4. Of the source/drain diffusion layers SD4, the one functioning as a source is connected to a conductive film Rig via contact holes CH7. The conductive film Mlg functions as the power supply line 42B. Of the source/drain diffusion layers SD4, the one functioning as a drain is connected to the conductive film M1h via contact holes CH9.

A conductive film M2b is arranged above the conductive film M1h in an overlapping position when seen in a plan view, whereby the capacitive element 110AB is formed.

Note that the specific structures of the capacitive element 110AB and the switch elements 130A and 130B are not limited to the examples shown in FIGS. 12 to 15. Any structures and layout may be employed.

The second embodiment of the present invention will be explained next.

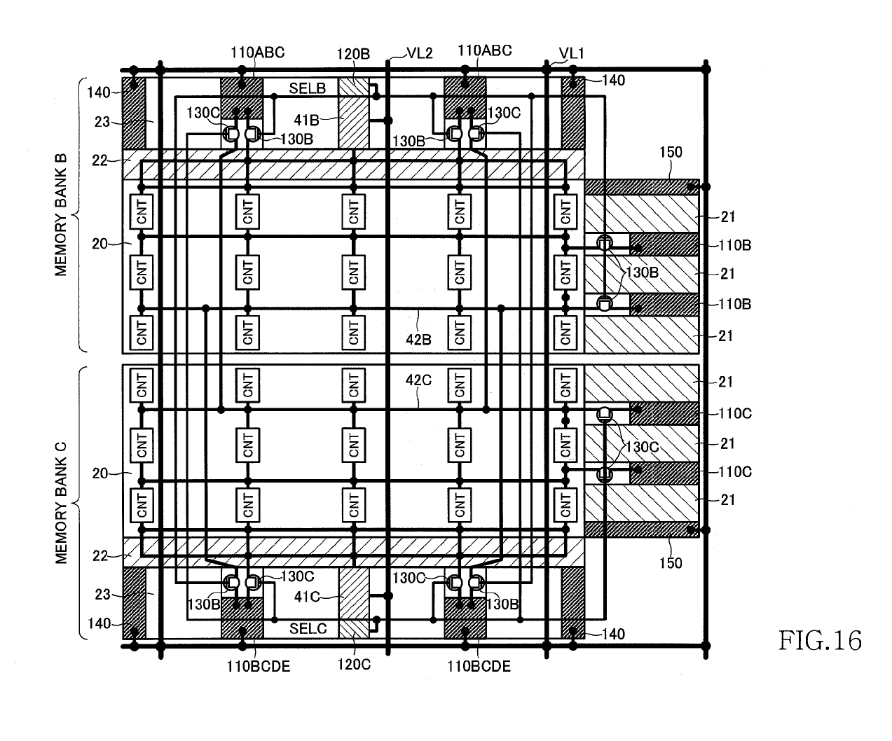

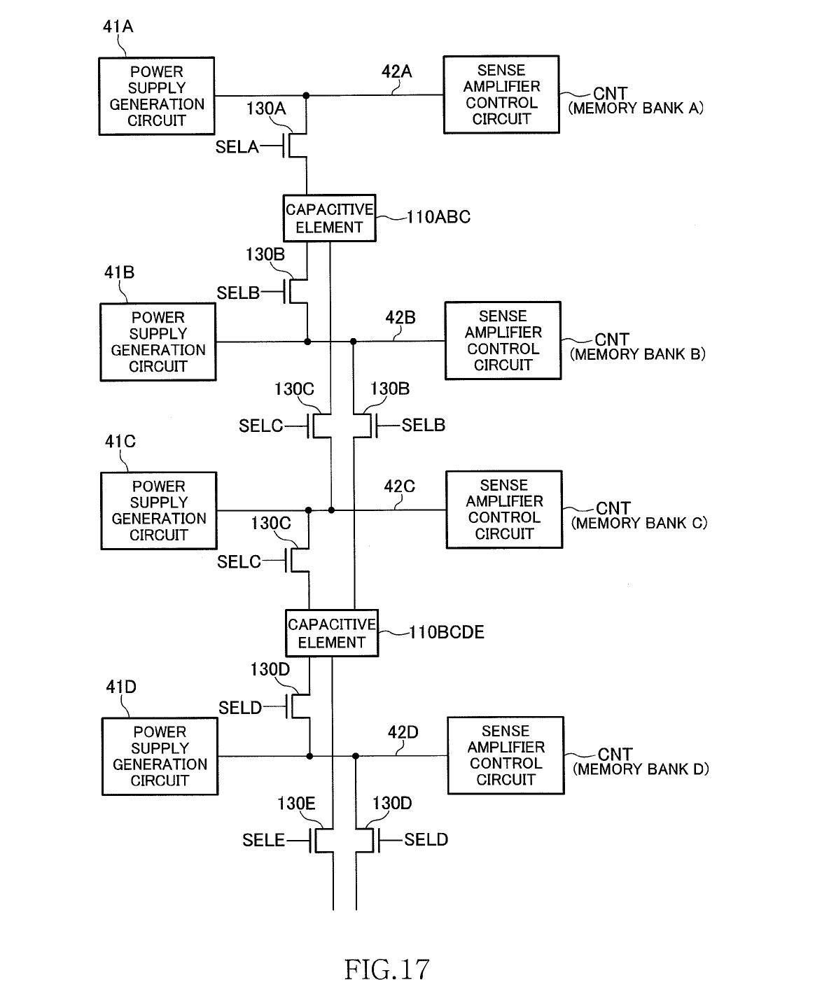

As shown in FIG. 16, in the second embodiment of the present invention, each capacitive element is allocated for three or four memory banks in common. Specifically, capacitive elements 110ABC are connected to the power supply lines 42A to 42C through the switch elements 130A to 130C, and thereby allocated for the three memory banks A to C in common. Capacitive elements 110BCDE are connected to the power supply lines 42B to 42E through the switch elements 130B to 130E, and thereby allocated for the four memory banks B to E in common. FIG. 17 is a simplified circuit diagram showing essential parts of the circuit according to the present embodiment. In the present Specification, the switch element (s) 130C connected to the capacitive element ABC among the switch elements 130C shown in FIG. 16 or 17 may be referred to as a “third switch element.” Among the switch elements 130B, the one(s) connected to the capacitive element 110BCDE may be referred to as a “fourth switch element.” The capacitive element 110BCDE may be referred to as a “second capacitive element.” The power supply generation circuit 41C may be referred to as a “third power supply generation circuit.”

As shown in FIG. 16, the capacitive elements 110ABC are connected to a far end of the power supply line 42C through switch elements 130C. Similarly, the capacitive elements 110BCDE are connected to a far end of the power supply line 42B through switch elements 130B. A far end of a power supply line refers to an end area farther from the corresponding power supply generation circuit. Far ends of the power supply lines tend to vary in voltage due to large wiring distances from the power supply generation circuits. In the present embodiment, the connection of the capacitive elements to the far ends of the power supply lines can prevent voltage variations at the far ends. No capacitive element needs to be added to the first embodiment. Since voltage variations at the far ends are prevented, the capacitive elements can be reduced in size accordingly. This allows a reduction in the chip size.

The third embodiment of the present invention will be explained next.

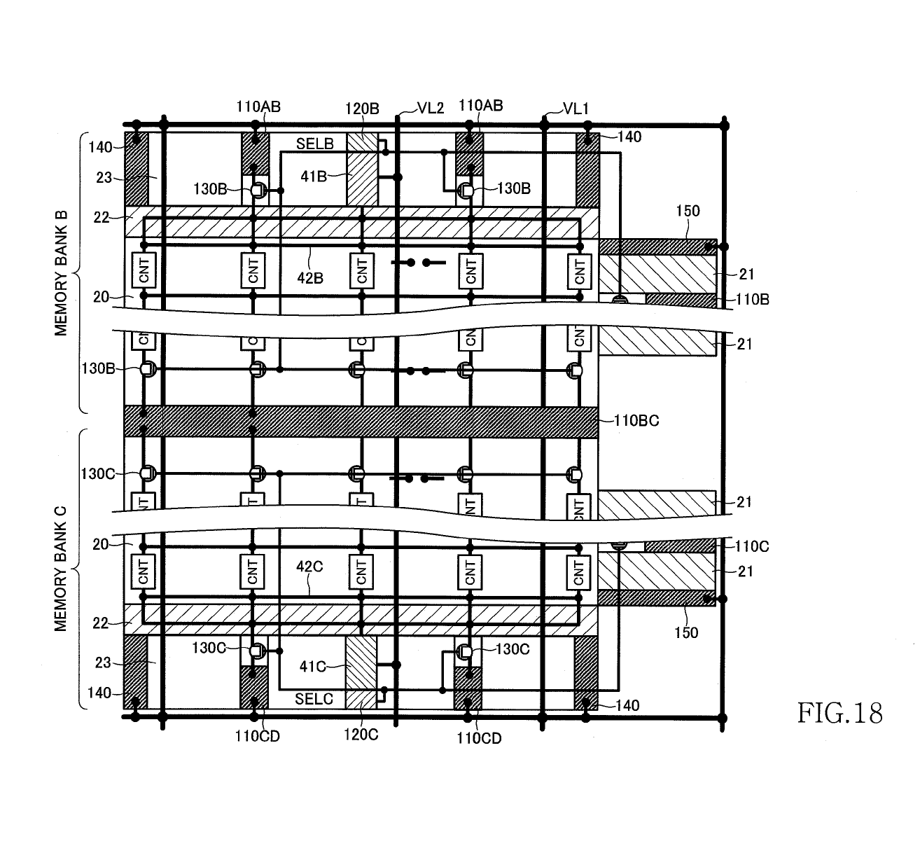

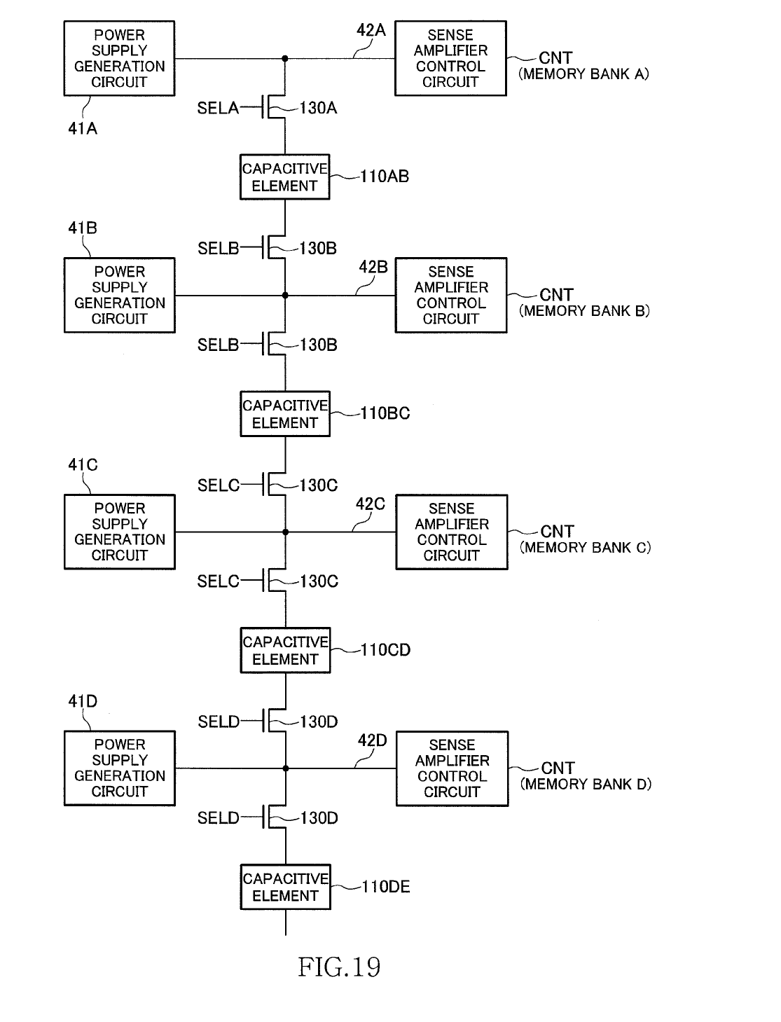

As shown in FIG. 18, in the third embodiment of the present invention, a capacitive element is added to between two adjoining memory banks without the interposition of the Y decoders 22 or the amplifier circuits 23. More specifically, a capacitive element 110BC is arranged between the memory banks B and C. The capacitive element 110BC is connected to the power supply lines 42B and 42C through the switch elements 130B and 1300, respectively. FIG. 19 is a simplified circuit diagram showing essential parts of the circuit according to the present embodiment. In the present Specification, the switch element(s) 130C connected to the capacitive element 110CD among the switch elements 130C shown in FIG. 18 or 19 may be referred to as a “fifth switch element.” Among the switch elements 130B, the one(s) connected to the capacitive element 110BC may be referred to as a “sixth switch element.” Among the switch elements 130C, the one(s) connected to the capacitive element 110BC may be referred to as a “seventh switch element.”

As shown in FIG. 18, the capacitive element 110BC is connected to far ends of the power supply lines 42B and 42C through the switch elements 130B and 130C. Even in the present embodiment, voltage variations at the far ends can thus be prevented. According to the present embodiment, the number of capacitive elements needs to be increased as compared to the first embodiment. However, since voltage variations at the far ends can be prevented, the capacitive elements can be reduced in size accordingly. This prevents an increase in the chip size.

The fourth embodiment of the present invention will be explained next.

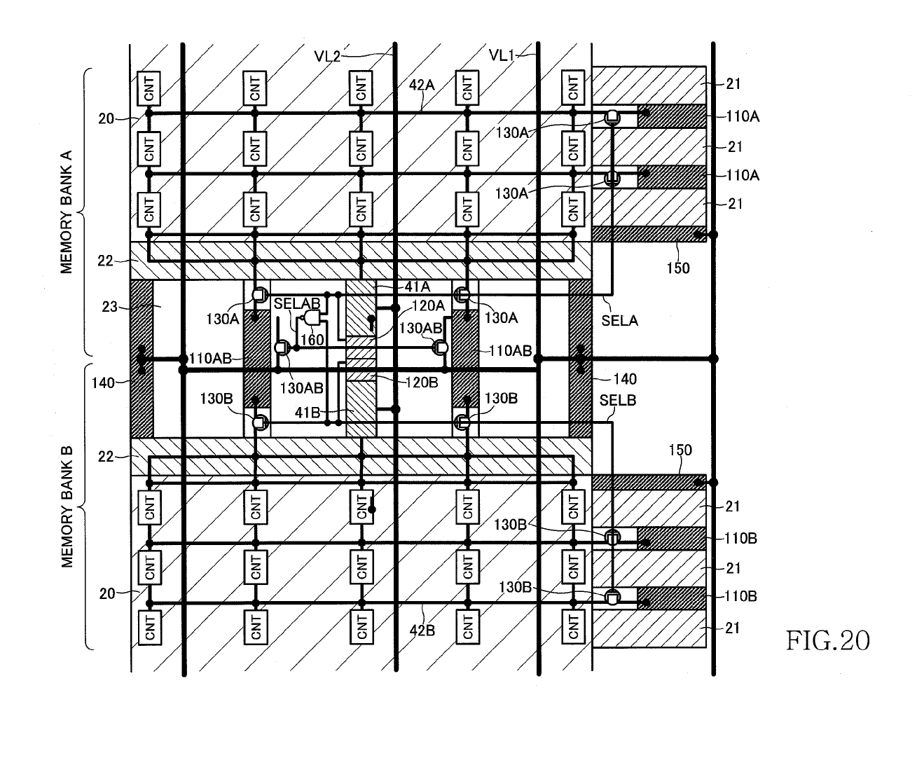

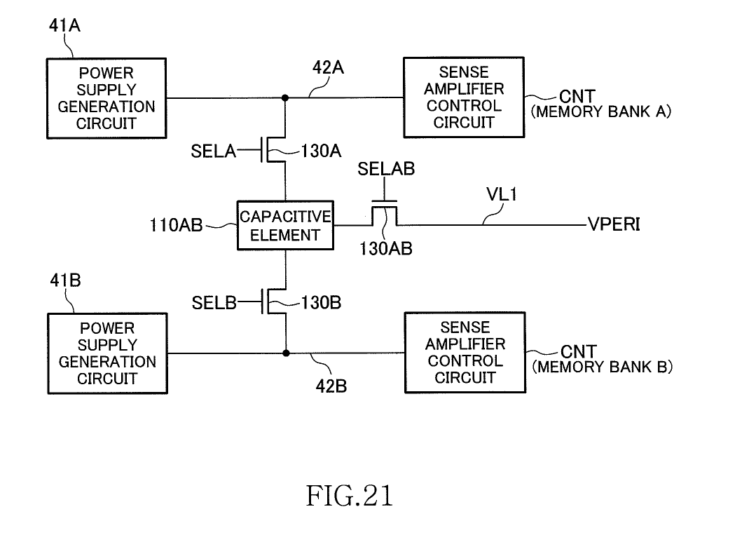

As shown in FIG. 20, the fourth embodiment of the present invention includes an additional NAND gate circuit 160 and additional switch circuits 130AB. The NAND gate circuit 160 receives the select signals SELA and SELB. The switch circuits 130AB receive a select signal SELAB output from the NAND gate circuit 160. The switch circuits 130AB are connected between the power supply line VL1 to which the internal voltage VPERI is supplied and the capacitive elements 110AB. In other respects, the basic configuration is almost the same as that of the first embodiment. FIG. 21 is a simplified circuit diagram showing essential parts of the circuit shown in FIG. 20.

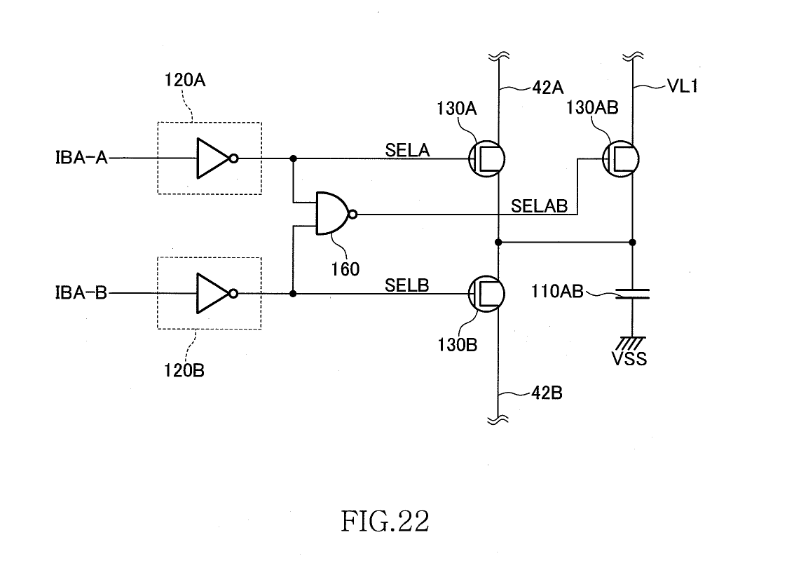

As shown in FIG. 22, the capacitance control circuits 120A and 120B according to the fourth embodiment of the present invention include an inverter circuit that receives the bank select signals IBA-A and IBA-B, respectively. With such a configuration, the NAND gate circuit 160 activates the select signal SELAB to a low level if the memory banks A and B are both in an unselected state. In the other cases, the NAND gate circuit 160 deactivates the select signal SELAB to a high level. As shown in FIG. 22, in the present embodiment, the switch element 130AB is composed of a P-channel MOS transistor. When the select signal SELAB is activated to a low level, the power supply line VL1 is thus connected to one end of the capacitive element 110AB.

An operation of the capacitance circuit 100 according to the fourth embodiment will be explained next.

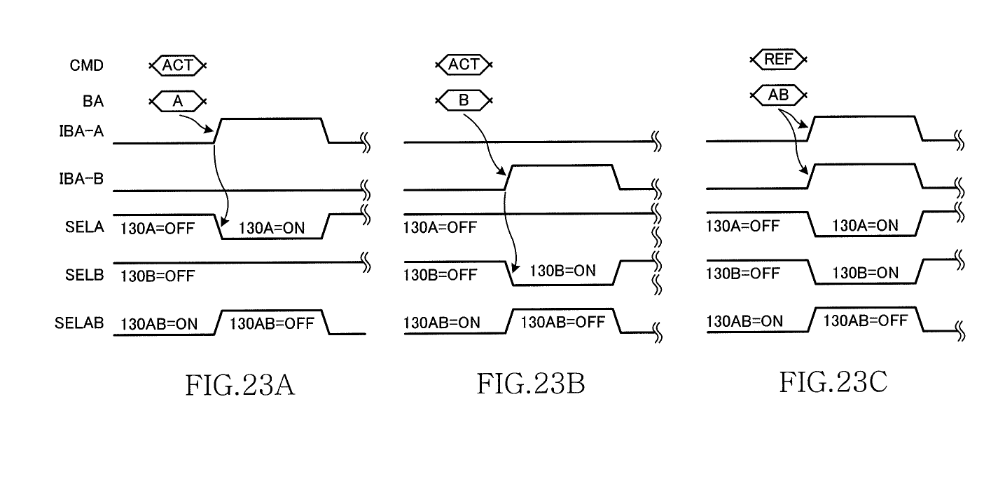

As shown in FIG. 23A, before the issuance of an active command ACT, i.e., when neither of the memory banks A and B is selected, the select signals SELA and SELB are both at a high level. Both the switch elements 130A and 130B are therefore off. Since the select signal SELAB is at a low level, the switch element 130 is on. As a result, the capacitive element 110AB is connected to the power supply line VL1, which contributes to the stabilization of the internal voltage VPERI. Here, the power supply generation circuits 41A and 41B are both in an inactive state, and are supplying currents to the inactive memory banks A and B with such ability as maintains the levels of the internal voltages VOD and VARY.

When an active command ACT designated for the memory bank A is issued, the bank select signal IBA-A changes to a high level. Consequently, the switch element 130A turns on and the switch element 130AB turns off, whereby the capacitive element 110AB is connected to the power supply line 42A and disconnected from the power supply line VL1. In response to the bank select signal IBA-A, the power supply generation circuit 41A is activated to enhance the ability to drive the internal voltages VOD and VARY on the power supply line 42A.

The operation when the memory bank B is selected is similar to the foregoing. As shown in FIG. 23B, the switch element 130B turns on and the switch element 130AB turns off, whereby the capacitive element 110AB is connected to the power supply line 42B and disconnected from the power supply line VL1. In response to the bank select signal IBA-B, the power supply generation circuit 41B is activated to enhance the ability to drive the internal voltages VOD and VARY on the power supply line 42B.

As shown in FIG. 23C, when a refresh command REF designated for the memory banks A and B is issued, the bank select signals IBA-A and IBA-B both change to a high level. Consequently, the switch elements 130A and 130B turn on and the switch element 130AB turns off, whereby the capacitive element 110AB is connected to the power supply lines 42A and 42B and disconnected from the power supply line VL1. In response to the bank select signals IBA-A and IBA-B, the power supply generation circuits 41A and 41B are activated to enhance the ability to drive the internal voltages VOD and VARY on the power supply lines 42A and 42B.

As described above, in the present embodiment, when the memory banks A and B are both in an inactive state, the capacitive element 110AB allocated for the memory banks A and B is connected to the power supply line VL1. The capacitive element 110AB thus contributes to the stabilization of the internal voltage VPERI which is supplied to the peripheral circuits. This allows a significant reduction in the size of a capacitive element that is dedicated to the power supply line VL1. In some cases, the capacitive element dedicated to the power supply line VL1 can be even omitted.

It is apparent that the present invention is not limited to the above embodiments, but may be modified and changed without departing from the scope and spirit of the invention.

What is claimed is:

1. A device comprising:
first and second memory cell arrays each including a plurality of memory cells;
a first power supply line supplying a first voltage to the first memory cell array;
a second power supply line supplying the first voltage to the second memory cell array; and
a first capacitive element, wherein
the first capacitive element is electrically connected to the first power supply line and is electrically disconnected from the second power supply line when the first memory cell array is activated and the second memory cell array is deactivated, and
the first capacitive element is electrically connected to the second power supply line and is electrically disconnected from the first power supply line when the second memory cell array is activated and the first memory cell array is deactivated.

2. The device as claimed in claim 1, further comprising:
a first switch element connected between the first capacitive element and the first power supply line;
a second switch element connected between the first capacitive element and the second power supply line; and
a capacitance control circuit controlling the first and second switch elements,
wherein the capacitance control circuit brings the first switch element into an ON state when the first memory cell array is activated, brings the second switch element into an ON state when the second memory cell array is activated, brings the first switch element into an OFF state when the second memory cell array is activated and the first memory cell array is deactivated, and brings the second switch element into an OFF state when the first memory cell array is activated and the second memory cell array is deactivated.

3. The device as claimed in claim 1, further comprising:
a first power supply generation circuit supplying the first voltage to the first power supply line; and
a second power supply generation circuit supplying the first voltage to the second power supply line, wherein
the first power supply generation circuit is activated when the first memory cell array is activated, and
the second power supply generation circuit is activated when the second memory cell array is activated.

4. The device as claimed in claim 1, further comprising:
a third memory cell array including a plurality of memory cells;
a third power supply line supplying the first voltage to the third memory cell array; and
a second capacitive element, wherein
the second capacitive element is electrically connected to the second power supply line when the second memory cell array is activated, and
the second capacitive element is electrically connected to the third power supply line when the third memory cell array is activated.

5. The device as claimed in claim 4, wherein the first capacitive element is electrically connected to the third power supply line when the third memory cell array is activated.

6. The device as claimed in claim 1, wherein the first capacitive element is electrically connected to the first and second power supply lines when neither of the first and second memory cell arrays is activated.

7. The device as claimed in claim 1, wherein the first capacitive element is electrically disconnected from the first and second power supply lines when neither of the first and second memory cell arrays is activated.

8. The device as claimed in claim 7, further comprising:
a peripheral circuit allocated for the first and second memory cell arrays in common; and
a fourth power supply line supplying a second voltage to the peripheral circuit,
wherein the first capacitive element is electrically connected to the fourth power supply line when neither of the first and second memory cell arrays is activated.

9. The device as claimed in claim 1, further comprising first and second memory banks selected according to a bank address signal, the first and second memory banks including the first and second memory cell arrays, respectively.

10. The device as claimed in claim 1, wherein
each of the first and second memory cell arrays includes a plurality of word lines and a plurality of bit lines that are connected to the plurality of memory cells, respectively, and a plurality of sense amplifier circuits that are connected to the plurality of bit lines, respectively, and
the first power supply line is connected to the sense amplifier circuits included in the first memory cell array, and
the second power supply line is connected to the sense amplifier circuits included in the second memory cell array.

11. A device comprising:
first and second memory cell arrays each including a plurality of memory cells and a plurality of sense amplifier circuits that amplify data read from the memory cells, respectively;
a first power supply generation circuit arranged in a first circuit area between the first and second memory cell arrays and supplying a first voltage to the sense amplifier circuits of the first memory cell array via a first power supply line;
a second power supply generation circuit arranged in the first circuit area and supplying the first voltage to the sense amplifier circuits of the second memory cell array via a second power supply line;
a first capacitive element arranged in the first circuit area;
a first switch element connected between the first capacitive element and the first power supply line;
a second switch element connected between the first capacitive element and the second power supply line; and
a capacitance control circuit controlling the first and second switch elements, the capacitance control circuit being configured to bring the first switch element into an ON state and the second switch element into an OFF state when the first memory cell array is activated and the second memory cell array is deactivated, and bring the second switch element into an ON state and the first switch element into an OFF state when the second memory cell array is activated and the first memory cell array is deactivated.

12. The device as claimed in claim 11, further comprising:
a third memory cell array including a plurality of memory cells and a plurality of sense amplifier circuits that amplifies data read from the plurality of memory cells, the first, second and third memory cell arrays being nonexclusively activated;
a third power supply generation circuit arranged in a second circuit area and supplying the first voltage to the sense amplifier circuits of the third memory cell array via a third power supply line; and
a third switch element connected between the first capacitive element and the third power supply line, wherein
the third memory cell array is arranged between the second memory cell array and the second circuit area, and
the capacitance control circuit brings the third switch element into an ON when the third memory cell array is activated.

13. The device as claimed in claim 12, further comprising:
a second capacitive element arranged in the second circuit area;
a fourth switch element connected between the second capacitive element and the second power supply line; and
a fifth switch element connected between the second capacitive element and the third power supply line,
wherein the capacitance control circuit brings the fourth switch element into an ON state when the second memory cell array is activated, and brings the fifth switch element into an ON state when the third memory cell array is activated.

14. The device as claimed in claim 11, further comprising:
a third memory cell array including a plurality of memory cells and a plurality of sense amplifier circuits that amplifies data read from the plurality of memory cells, the first, second and third memory cell arrays being nonexclusively activated;
a third power supply generation circuit arranged in a second circuit area and supplying the first voltage to the sense amplifier circuits of the third memory cell array via a third power supply line;
a second capacitive element arranged in the second circuit area;
a third capacitive element arranged in a third circuit area;
a fifth switch element connected between the second capacitive element and the third power supply line;
a sixth switch element connected between the third capacitive element and the second power supply line; and
a seventh switch element connected between the third capacitive element and the third power supply line, wherein
the third circuit area is arranged between the second memory cell array and the third memory cell array,
the third memory cell array is arranged between the second circuit area and the third circuit area, and
the capacitance control circuit brings the sixth switch element into an ON state when the second memory cell array is activated, and brings the fifth and seventh switch elements into an ON state when the third memory cell array is activated.

15. The device as claimed in claim 11, further comprising:
a peripheral circuit allocated for the first and second memory cell arrays in common; and
a fourth power supply line supplying a second voltage to the peripheral circuit,
wherein the first capacitive element is electrically connected to the fourth power supply line when neither of the first and second memory cell arrays is activated.

16. A device comprising:
a first sense amplifier array for a first memory cell array;
a second sense amplifier array for a second memory cell array;
a first power line conveying a first power voltage to the first sense amplifier array;
a second power line conveying a second power voltage to the second sense amplifier array, the second power voltage being substantially equal to the first power voltage;
a common capacitor;
a first switch connected between the first power line and the common capacitor, the first switch being configured to be one of conductive and non-conductive states in response to a first control signal; and
a second switch connected between the second power line and the common capacitor, the second switch being configured to be one of conductive and non-conductive states in response to a second control signal.

17. The device as claimed in claim 16, further comprising a first individual capacitor connected to the first power line and a second individual capacitor connected to the second power line.

18. The device as claimed in claim 16, further comprising a first power circuit coupled to the first power line to supply the first power voltage thereto, and a second power supply circuit coupled to the second power line to supply the second power voltage thereto.

19. The device as claimed in claim 16, wherein the first control signal takes an active level to render the first switch conductive when the first sense amplifier array is activated, and the second signal takes an active level to render the second switch conductive when the second sense amplifier array is activated.

20. The device as claimed in claim 18,
wherein the first power circuit supplies the first power voltage to the first power line with a first driving ability when the first sense amplifier array is deactivated and with a second driving ability when the first sense amplifier array is activated, the first driving ability being less than the second driving ability;
wherein the second power circuit supplies the second power voltage to the second power line with a third driving ability when the second sense amplifier array is deactivated and with a fourth driving ability when the second sense amplifier array is activated, the third driving ability being less than the fourth driving ability; and
wherein the first control signal takes an active level to render the first switch conductive when the first sense amplifier array is activated, and the second signal takes an active level to render the second switch conductive when the second sense amplifier array is activated.
